(19) United States
(12) Patent Application Publication
(10) Pub. No.: US 2021/0035823 A1
(43) Pub. Date: Feb. 4, 2021

(54) SUBSTRATE PROCESSING DEVICE

(71) Applicant: Tokyo Electron Limited, Tokyo (JP)

(72) Inventors: Yuji ASAKAWA, Nirasaki City, Yamanashi (JP); Manabu AMIKURA, Nirasaki City, Yamanashi (JP)

(21) Appl. No.: 16/766,967

(22) PCT Filed: Nov. 16, 2018
(86) PCT No.: PCT/JP2018/042523

§ 371 Date: May 26, 2020

(30) Foreign Application Priority Data
Nov. 30, 2017 (JP) 2017-230140

(51) Int. Cl. H01L 21/67

(52) U.S. Cl. CPC H01L 21/67069; H01L 21/67126

(57) ABSTRACT

A substrate processing device for processing a substrate is provided. The substrate processing device includes: a processing container configured to accommodate a substrate; a placement stage on which the substrate is mounted in the processing container; an exhauster configured to exhaust a processing gas in the processing container; and a partition wall disposed in the processing container and surrounding the placement stage, wherein, inside the partition wall, an exhaust flow path, which communicates with the exhauster, is formed to extend in a vertical direction over an entire circumference of the partition wall, and a plurality of openings, which communicates with a substrate processing space formed inside the partition wall above the placement stage and communicates with the exhaust flow path, is formed at regular intervals in an inner circumferential direction of the partition wall.

### CROSS-REFERENCE TO RELATED APPLICATIONS

The present application is based on and claims priority from Japanese Patent Application No. 2017-230140 filed in Japan on Nov. 30, 2017, the disclosure of which is incorporated herein in its entirety by reference.

The present disclosure relates to a substrate processing device used when performing predetermined processing on a substrate.

### TECHNICAL FIELD

### Background

Recently, with the miniaturization of semiconductor devices, a method that enables finer etching, called chemical oxide removal (COR) processing, has been used instead of conventional etching techniques such as plasma etching and wet etching.

The COR processing means processing in which a processing gas is supplied to, for example, a semiconductor wafer (hereinafter, referred to as a “wafer”) as a target object in a processing container held in a vacuum and the processing gas is reacted with, for example, a film formed on the wafer, thereby producing a product. The product produced on the wafer surface by the COR processing is sublimated by performing a heating treatment in the next step, whereby the film on the wafer surface is removed.

Such COR processing is performed in a single-wafer processing device that processes wafers one by one. However, in recent years, a processing device that simultaneously processes a plurality of wafers is used in some cases in order to improve throughput (Patent Document 1).

In the processing device of Patent Document 1, it has been proposed to provide a buffer plate that vertically divides the inside of the processing container into a processing space and an exhaust space in order to prevent the flow of the processing gas from becoming uneven on the surfaces of a plurality of (e.g., two) wafers.

### PRIOR ART DOCUMENTS

### Patent Documents

Patent Document 1: Japanese Laid-Open Patent Publication No. 2012-146854

### SUMMARY

However, in recent years, a demand for uniformity of wafer processing has become strict. For this reason, with the configuration in which a buffer plate that simply divides the inside of the processing chamber into a processing space and an exhaust space is provided and the atmosphere in the processing space is exhausted from below the buffer plate, it is difficult to appropriately control the flow of the processing gas, that is, the uniformity and the flow velocity. Therefore, there is room for improvement particularly in the processing uniformity in the peripheral portion of a wafer and the processing uniformity between the peripheral portion and the central portion of the wafer.

The present disclosure has been made in view of the above points, and an object of the present disclosure is to improve in-plane uniformity of substrate processing by improving the uniformity of the exhaust of a processing gas.

An aspect of the present disclosure for solving the above problems is a substrate processing device for processing a substrate, wherein the substrate processing device includes: a processing container configured to accommodate a substrate therein; a placement stage configured to place the substrate thereon in the processing container; an exhauster configured to exhaust a processing gas in the processing container; and a partition disposed in the processing container and surrounding the placement stage. Inside the partition wall, an exhaust flow path, which communicates with the exhauster, is formed to extend in a vertical direction over the entire circumference thereof, and a plurality of openings, which communicate with a substrate processing space formed inside the partition wall and above the placement stage and with the exhaust flow path, are formed at regular intervals in the inner circumferential direction of the partition wall.

According to one embodiment of the present disclosure, when the processing gas used for substrate processing is exhausted from the substrate processing space, the processing gas flows from the peripheral portion on the substrate toward the partition wall side, passes through the plurality of openings formed in the inner circumference of the partition wall in the circumferential direction thereof, and flows out into the exhaust flow path inside the partition wall. Then, the processing gas is exhausted from the exhaust flow path via the exhauster. Since the openings are evenly formed along the circumferential direction of the partition wall, the processing gas uniformly flows toward the partition wall in the state in which the flow velocity is decelerated. In addition, since the exhaust flow path, which communicates with the openings, is formed in the partition wall so as to extend in the vertical direction, it is possible to appropriately maintain the decelerated state. As a result, in the peripheral portion of the substrate, it is possible to sufficiently decelerate the flow velocity within a range where the processing gas does not stay in the peripheral portion. Moreover, it is possible to make the processing gas uniformly flow. Accordingly, even in the peripheral portion, it is possible to realize the processing using the processing gas such that there is no difference between the central portion and the peripheral portion of the substrate. Moreover, it is also possible to realize uniform processing in the peripheral portion of the substrate.

According to an embodiment of the present disclosure, when processing is performed using a processing gas by supplying the processing gas to a substrate on the placement stage in the processing container, it is possible to make the exhaust flow velocity of the processing gas appropriate and uniform. Thus, it is possible to improve in-plane uniformity of substrate processing.

### BRIEF DESCRIPTION OF DRAWINGS

FIG. 1 is a vertical cross-sectional view schematically illustrating a configuration of a wafer processing device according to the present embodiment.

FIG. 2 is a perspective view schematically illustrating a configuration of a partition wall.

FIG. 3 is a perspective view illustrating the partition wall of FIG. 2 disassembled into respective components.

FIG. 4 is a perspective view schematically illustrating a configuration of a principal part in the partition wall.

FIG. 5 is a vertical cross-sectional view schematically illustrating the configuration of the wafer processing device according to the present embodiment in a case in which the partition wall is lowered to a substrate transport position.

FIG. 6 is an explanatory view illustrating a positional relationship between an opening area and a wafer on a placement stage.

FIG. 7 is a perspective view of the partition wall viewed obliquely from below.

FIG. 8 is an explanatory view illustrating the flow of a processing gas in the wafer processing device according to the present embodiment.

FIG. 9 is an explanatory view illustrating the flow of a processing gas in a principal part in a conventional wafer processing device.

FIG. 10 is an explanatory view illustrating the flow of a processing gas in a principal part in the wafer processing device according to the present embodiment.

FIG. 11 is a graph representing a distribution relationship of gas flow velocities at respective wafer surface positions in the wafer processing device of FIG. 9.

FIG. 12 is a graph representing a distribution relationship of gas flow velocities at respective wafer surface positions in the wafer processing device of FIG. 10.

FIG. 13 is a perspective view of a partition wall, in which a configuration of slits in another embodiment of the present disclosure is illustrated.

FIG. 14 is an explanatory view illustrating the flow of a gas when the opening area is set in the upper half of the portion forming the lateral circumferential surface of the processing space when the partition wall is located at a substrate processing position.

FIG. 15 is an explanatory view illustrating the flow of a gas when the opening area is set in the entire portion forming the lateral circumferential surface of the processing space when the partition wall is located at the substrate processing position.

FIG. 16 is a vertical cross-sectional view schematically illustrating a configuration of a wafer processing device according to another embodiment of the present disclosure.

### DETAILED DESCRIPTION

Hereinafter, embodiments of the present disclosure will be described with reference to the drawings. In the specification and drawings, elements having substantially the same functional configuration are denoted by the same reference numerals and redundant explanations are omitted.

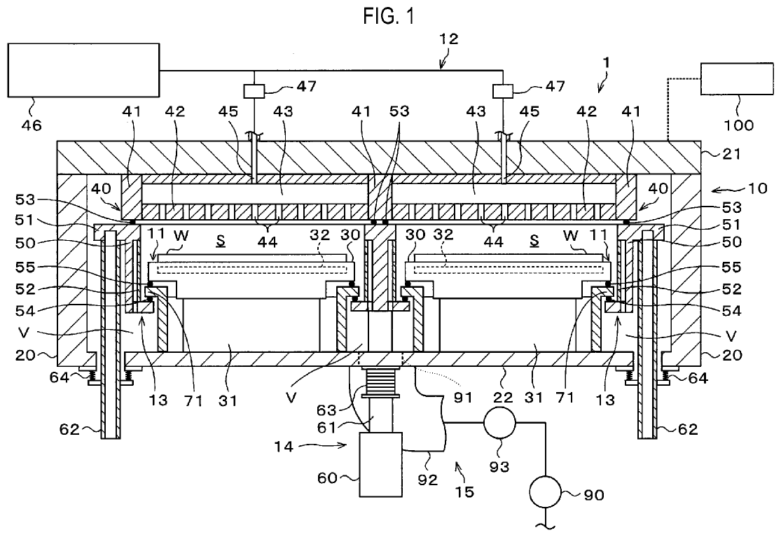

First, the configuration of a wafer processing device as a substrate processing device according to an embodiment of the present disclosure will be described. FIG. 1 is a vertical cross-sectional view schematically illustrating the configuration of a wafer processing device 1 according to the present embodiment. In the present embodiment, a case in which the wafer processing device 1 is a COR processing device, which performs COR processing, for example, on a wafer W, will be described.

As illustrated in FIG. 1, the wafer processing device 1 includes a hermetically configured processing container 10, a plurality of placement stages 11 (in the present embodiment, two placement stages) configured to place wafers W thereon in the processing container 10, a gas supplier 12 configured to supply a processing gas from above each of the placement stages 11 toward the placement stages 11, a partition wall 13 surrounding the outside of each of the placement stages 11 and configured to be capable of being raised and lowered, an elevator 14 fixed to the bottom surface of the processing container 10 and configured to raise and lower the partition wall 13, and an exhauster 15 configured to evacuate the inside of the processing container 10.

The processing container 10 is a substantially rectangular parallelepiped container as a whole, which is formed of a metal such as aluminum or stainless steel. The processing container 10 has, for example, a substantially rectangular shape when viewed in a plan view, and includes a cylindrical side wall 20 having an open top surface and an open bottom surface, a ceiling plate 21 that hermetically covers the top surface of the side wall 20, and a bottom plate 22 that covers the bottom surface of the side wall 20. In addition, a seal member (not illustrated) is installed between the upper end surface of the side wall 20 and the ceiling plate 21 so as to hermetically maintain the inside of the processing container 10. The processing container 10 is installed with a heater (not illustrated), and the bottom plate 22 is installed with a heat insulating material (not illustrated).

Each placement stage 11 is formed in a substantially cylindrical shape, and has an upper stage 30 having a placement surface on which the wafer W is placed, and a lower stage 31 fixed to the bottom plate 22 and supporting the upper stage 30. The upper stage 30 includes a temperature adjustment mechanism 32 embedded therein so as to adjust the temperature of the wafer W. The temperature adjustment mechanism 32 adjusts the temperature of the placement stage 11 by circulating a coolant such as water, and the temperature of the wafer W on the placement stage 11 is controlled to a predetermined temperature of, for example, −20 degrees C. to 140 degrees C.

In the bottom plate 22, a support pin unit (not illustrated) is installed at a position below each placement stage 11, and it is possible to deliver the wafer W placed on the placement stage 11 between a support pin (not illustrated) driven upward and downward by the support pin unit and a transport mechanism (not illustrated) installed outside the wafer processing device 1.

The gas supplier 12 includes shower heads 40 configured to supply a processing gas to wafers W placed on the placement stages 11. The shower heads 40 are separately installed on the bottom surface of the ceiling plate 21 of the processing container 10 so as to face the placement stages 11, respectively. Each shower head 40 has, for example, a substantially cylindrical frame 41 having an open bottom surface and supported on the bottom surface of the ceiling plate 21, and a substantially disk-shaped shower plate 42, which is fitted into the inner surface of the frame 41. In order to uniformly supply a processing gas to the entire surface of the wafer W placed on each placement stage 11, the shower plate 42 preferably has a diameter that is at least larger than the diameter of the wafer W. The shower plate 42 is installed at a predetermined distance from the ceiling portion of the frame 41. Therefore, a space 43 is formed between the ceiling portion of the frame 41 and the top surface of the shower plate 42. The shower plate 42 is installed with a plurality of openings 44 penetrating the shower plate 42 in the thickness direction.

A gas supply source 46 is connected to the space 43 between the ceiling portion of the frame 41 and the shower plate 42 via a gas supply pipe 45. The gas supply source 46 is configured to be capable of supplying, for example, hydrogen fluoride (HF) gas or ammonia (NH₃) gas, as the processing gas. Therefore, the processing gas supplied from the gas supply source 46 is supplied toward the wafer W placed on each of the placement stages 11 via the space 43 and the shower plate 42. In addition, each gas supply pipe 45 is installed with a flow rate adjustment mechanism 47 configured to adjust the supply amount of the processing gas so as to be capable of individually adjusting the amount of the processing gas to be supplied to each wafer W. In addition, each of the shower heads 40 may be of a post-mix type capable of individually supplying, for example, multiple types of processing gases without mixing the processing gases.

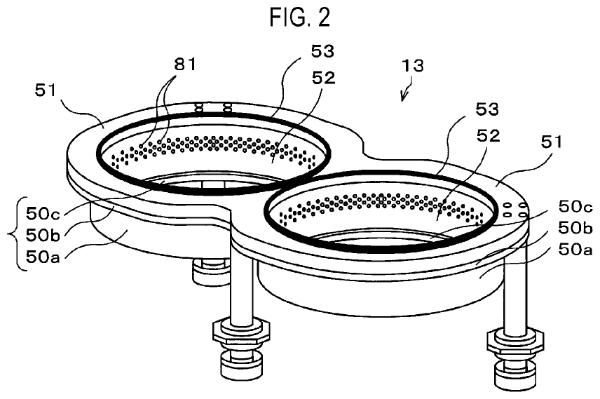

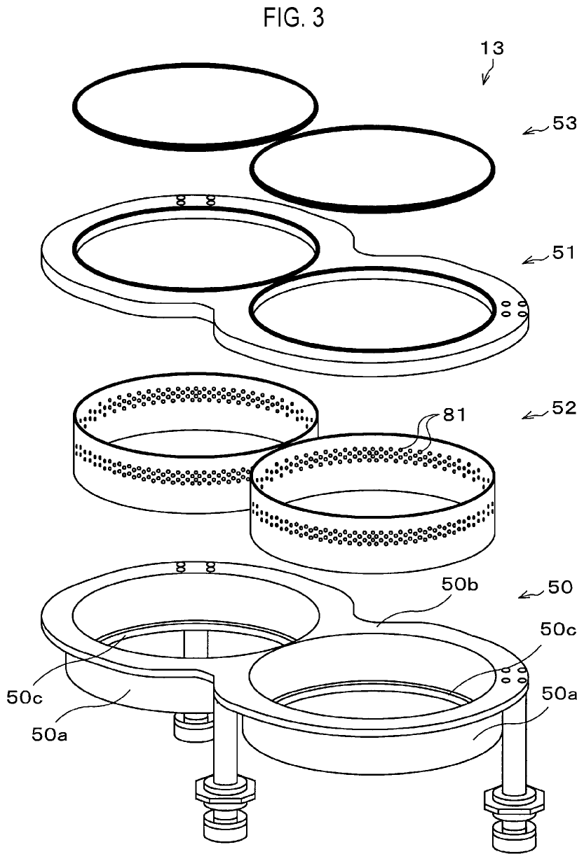

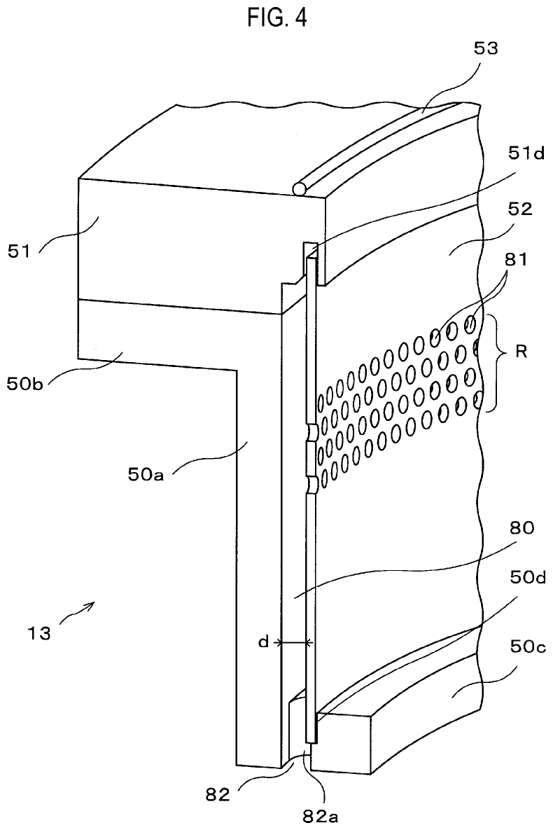

As illustrated in FIGS. 2 and 3, the partition wall 13 has a base body 50, and the base body 50 includes, for example, two cylinder portions 50a (each having an inner circumference having a circular shape when viewed in a plan view), which individually surround two placement stages 11, respectively, an upper flange portion 50b having a substantially “8” shape (a shape in which two annular rings adjoin each other) when viewed in a plan view and installed on the upper ends of the cylinder portions 50a, and a lower flange portion 50c having the substantially “8” shape when viewed in a plan view and installed on the lower ends of the cylinder portions 50a. On the top surface of the upper flange 50b, the base body 50 has a cover 51 having the substantially “8” shape when viewed in a plan view and hermetically installed. In addition, inside the two cylinder portions 50a, the base body 50 has exhaust rings 52. As illustrated in FIG. 4, the exhaust rings 52 are installed in the base body 50 in a state in which upper and lower ends of the exhaust rings 52 are respectively fitted into the grooves 50d and 51d, which are formed in the lower flange portion 50c and the cover 51, respectively. At that time, a predetermined spacing is installed between the inner surface of the cylinder portion 50a and the outer surface of the exhaust ring 52. This spacing constitutes a gap 80 to be described later.

In addition, the partition wall 13 is installed with a heater (not illustrated), and is heated to, for example, 100 degrees C. to 150 degrees C. Due to this heating, foreign matter contained in the processing gas is prevented from adhering to the partition wall 13.

In addition, the partition wall 13 is capable of being raised and lowered between a substrate processing position and a substrate transport position by the elevator 14. That is, as illustrated in FIG. 1, when the partition wall 13 is raised to the substrate processing position by the elevator 14, the frame 41 and the upper end surface of the cover 51 come into contact with each other and thus processing spaces S surrounded by the placement stages 11, the partition wall 13, and the shower heads 40 are formed in the processing container 10. In this case, in order to hermetically maintain the inside of the processing spaces S, the sealing members 53, such as O-rings, are installed on the upper surface of the cover 51.

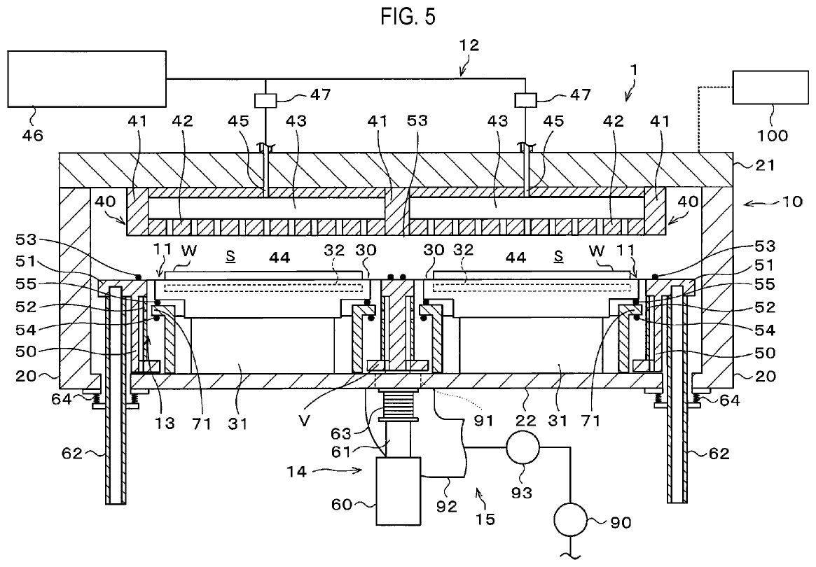

In addition, when the partition wall 13 is lowered to the substrate transport position by the elevator 14, as illustrated in FIG. 5, the partition wall 13 has a height such that the top surface of the cover 51 substantially coincides with the top surfaces of the placement stages 11. As a result, by lowering the partition wall 13, it becomes possible to access the wafer W, which is raised from the top surface of each placement table 11 by the support pin unit described above, from the outside of the processing container 10.

The elevator 14 configured to raise and lower the partition wall 13 includes an actuator 60 disposed outside the processing container 10, a drive shaft 61 connected to the actuator 60 and extending vertically upward in the processing container 10 while penetrating through the bottom plate 22 of the processing container 10, and a plurality of guide shafts 62 connected to the partition wall 13 at the distal ends thereof and extending to the outside of the processing container 10 at the other ends thereof. The guide shafts 62 prevents the partition wall 13 from being tilted when the partition wall 13 is raised or lowered by the drive shaft 61.

The drive shaft 61 is hermetically connected to the lower end portion of an extendable bellows 63. The upper end portion of the bellows 63 is hermetically connected to the bottom surface of the bottom plate 22. Therefore, when the drive shaft 61 is raised and lowered, the bellows 63 expands and contracts in the vertical direction so that the inside of the processing container 10 is hermetically maintained. In addition, between the drive shaft 61 and the bellows 63, for example, a sleeve (not illustrated) fixed to the bottom plate 22 is installed so as to function as a guide during the raising and lowering operation.

An extendable bellows 64 is connected to each of the guide shafts 62, similar to the drive shaft 61. In addition, the upper end portion of the bellows 64 is hermetically connected to both the bottom plate 22 and the side wall 20. Therefore, when the guide shafts 62 are raised and lowered according to the raising and lowering operation of the partition wall 13 by the drive shaft 61, each bellows 64 extends and contracts in the vertical direction so that the inside of the processing container 10 is hermetically maintained. A sleeve (not illustrated) that functions as a guide during the raising and lowering operation is also installed between each guide shaft 62 and each bellows 64, similar to the case of the drive shaft 61.

In addition, since the upper end portions of the bellows 64 are fixed end portions, and the lower end portions of the bellows 64 connected to the guide shafts 62 are free end portions, a force for compressing the bellows 64 in the vertical direction acts due to the pressure difference between the inside and outside of the bellows 64 when the inside of the processing container 10 becomes a negative pressure. Therefore, since the bellows 64 contract, the guide shafts 62 connected to the free end portions of the bellows 64 are raised vertically upward. Thereby, it is possible to ensure the sealing property between the partition wall 13 and the frame 41 by evenly raising the partition wall 13 and bringing the seal members 53 and the frame 41 into appropriate contact with each other. Similarly, it is possible to ensure the sealing property between the partition wall 13 and protrusions 71 by bringing the seal members 54 and the protrusions 71 into appropriate contact with each other. In addition, the guide shafts 62 are subjected to a reaction force from the bellows 64 serving as elastic members, or a force that pushes down the guide shafts 62 due to the weights thereof. Thus, by appropriately setting the diameters of the bellows 64, a differential pressure acting on the guide shafts 62 is adjusted. In addition, the protrusions 71 may be portions of an inner wall (as in the illustrated example), or may be portions of the placement stages 11 (not illustrated).

In addition, the upper ends of the protrusions 71 are in airtight contact with the bottom surfaces of the placement stages 11 via sealing members 55. When the partition wall 13 is raised and comes into contact with the protrusions 71 via the sealing members 54, it is possible to reliably ensure sealing property between the protrusions 71 and the partition wall 13. Accordingly, when the processing gas in the processing spaces S is exhausted, the processing gas is not discharged from the gap between the outer periphery of the placement stages 11 and the partition wall 13. Thus, it is possible to stabilize the flow of the processing gas in the vicinity of the outer peripheries of the placement stages 11.

FIG. 4 is an enlarged perspective view illustrating a vertical section of a partition wall 13. As described above, the exhaust ring 52 is installed to be spaced apart from the inner peripheral surface of the cylinder portion 50a of the base body 50, and a gap 80 extending in the vertical direction is formed between the inner peripheral surface of the cylinder portion 50a and the outer peripheral surface of the exhaust ring 52 over the entire circumference thereof. In this embodiment, the size of the gap 80, that is, the length d in the horizontal direction, is set to, for example, 3 to 5 mm.

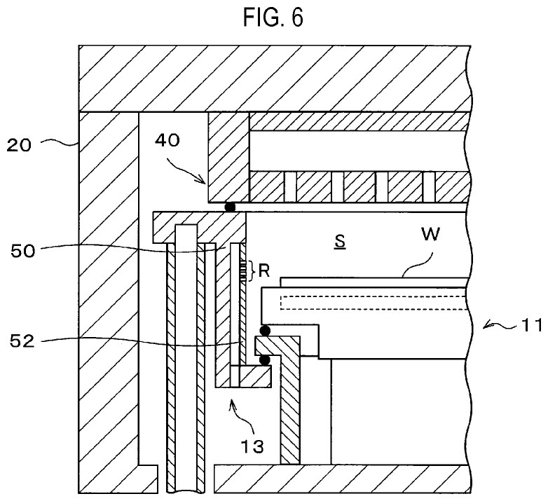

The exhaust ring 52 is installed with a plurality of openings 81 in an opening area R at regular intervals over the entire circumference thereof. The openings 81 in the present embodiment are circular holes each having a diameter of 3 mm. As illustrated in FIG. 6, the opening area R is set to include the same height position in the horizontal direction as the wafer W mounted on the placement stage 11 when the partition wall 13 is raised to the substrate processing position by the elevator 14. Of course, the shape of each opening is not limited to the circular hole. Each of the openings may have, for example, a slit shape, without being limited to the circular shape as long as the openings are formed at regular intervals over the entire circumference of the opening area R.

As described above, the partition wall 13 is set to include the height position of the wafer W on the placement stage 11 when the partition wall 13 is located at the substrate processing position and the processing space S is formed on the placement stage 11. However, the opening region R may of course be set over a predetermined range in the vertical direction. In such a case, as illustrated in FIG. 6, the opening area R is preferably formed in the lower half in the portion of the partition wall 13 that forms a lateral circumferential surface of the processing space S at the substrate processing position. Further, an appropriate opening ratio in the opening area R is preferably, for example, in a range of 50±5%, and is set to 48.9% in the present embodiment.

When the opening ratio is too large, that is, when the ratio occupied by the openings is too large, the flow velocity of the processing gas flowing into the gap 80 from the processing space S increases. Thus, processing in the peripheral portion of the wafer W placed on the placement stage 11, for example, etching, becomes insufficient. In contrast, when the opening ratio is too small, that is, when the ratio occupied by the wall surface of the exhaust ring 52 is too large, the processing gas does not sufficiently flow into the gap 80. Thus, the stagnation of the processing gas occurs in the processing space S or the processing gas stays in the peripheral portion of the wafer W. Therefore, it is necessary to form the plurality of openings 81 in a suitable opening ratio such that these problems do not occur. The above-mentioned preferable range of the opening ratio of 50±5% was found by the inventors based on tests and the like in consideration of these circumstances.

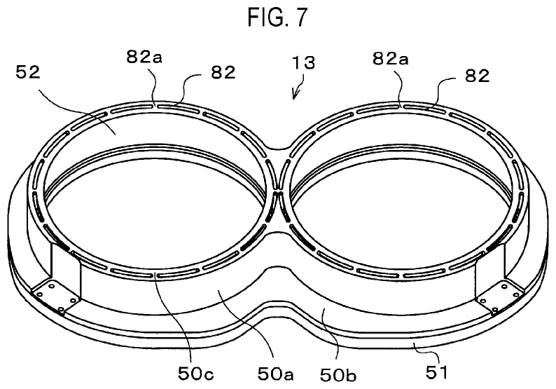

As illustrated in FIGS. 4 and 7, a plurality of slits 82 are formed at predetermined intervals over the entire circumference near the lower end of the partition wall 13. In order to properly maintain the size of the gap 80 formed between the inner circumferences of cylinder portions 50a and the outer circumference of the exhaust rings 52 below the gap 80, which becomes an exhaust flow path, the slits 82 are formed by beams 82a installed therebetween. Due to the slits 82 formed by the beams 82a, the cross-sectional area of the exhaust flow path is smaller in the lower portion of the exhaust flow path in the partition wall 13 than in the upper portion of the exhaust flow path. The exhaust gas passing through the gap 80 and the slits 82 is guided to the exhauster 15 of the processing container 10.

As illustrated in FIG. 1, the exhauster 15 has an exhaust mechanism 90 configured to evacuate the inside of the processing container 10. The exhauster 15 has an exhaust port 91 installed outside the partition walls 13 in the bottom plate 22 of the processing container 10. That is, the exhaust port 91 is installed in the bottom plate 22 outside the partition walls 13 at a position not overlapping the partition walls 13 when viewed in a plan view. The exhaust port 91 communicates with an exhaust pipe 92.

The two processing spaces S formed by the two partition walls 13 shares the exhaust mechanism 90, the exhaust port 91, and the exhaust pipe 92. That is, the slits 82 formed in each of the two partition walls 13 communicate with a common exhaust space V formed below in the processing container 10, and the processing gas flowing into the exhaust space V is exhausted by the exhaust mechanism 90 via the common exhaust pipe 92. The exhaust pipe 92 is installed with a regulation valve 93 configured to regulate the exhaust amount by the exhaust mechanism 90. In addition, the ceiling plate 21 is installed with a pressure measurement mechanism (not illustrated) configured to measure the pressure in the processing space S of each of the placement stages 11. The opening degree of the regulation valve 93 is controlled based on, for example, a measurement value obtained by the pressure measurement mechanism.

The wafer processing device 1 is installed with a control device 100. The control device 100 is, for example, a computer, and has a program storage (not illustrated). The program storage stores a program for controlling the processing of the wafer W in the substrate processing device 1. The program may be stored in a computer-readable storage medium such as a computer-readable hard disk (HD), a flexible disk (PD), a magneto-optical disk (MO), or a memory card, and may be installed to the control device 100 from the storage medium.

The wafer processing device 1 according to the present embodiment is configured as described above. Next, wafer processing in the wafer processing device 1 will be described.

In wafer processing, first, as illustrated in FIG. 5, the partition walls 13 are lowered to the substrate transport position by the elevator 14. In this state, wafers W are transported into the processing container 10 by a wafer transport mechanism (not illustrated) installed outside the wafer processing device 1, the wafers W are delivered onto support pins (not illustrated), and the wafers W are placed on the placement table 11 by lowering the support pins.

Thereafter, as illustrated in FIG. 1, the partition walls 13 are raised to the wafer processing position by the elevator 14. As a result, the frame 41 and the cover 51 come into contact with each other via the seal members 53, and thus two processing spaces S are formed in the processing container 10.

Then, for a predetermined time, the inside of the processing container 10 is evacuated to a predetermined pressure by the exhaust mechanism 90, and when a processing gas is supplied from the gas supply source 46 into the processing container 10, predetermined processing (e.g., COR processing in the present embodiment) is performed on the wafers W.

In the COR processing, the processing gas supplied from the gas supply source 46 is uniformly supplied to the wafers W via the shower plates 42, and predetermined processing is performed. In view of the uniformity of supply of the processing gas to the wafers W, it is more advantageous that the shower plate 42 has a diameter that is at least larger than the diameter of the wafer W.

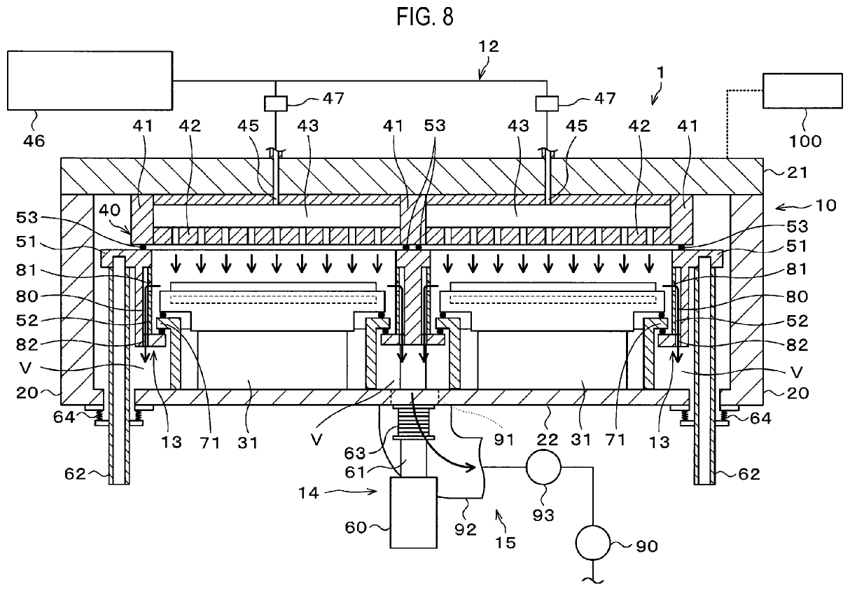

Subsequently, as illustrated in FIG. 8, the processing gas supplied to the wafers W is discharged from the processing container 10 by the exhaust mechanism 90 from the openings 81 formed in the exhaust rings 52 of the partition walls 13, and through the gaps 80 in the partition walls 13, the exhaust space V, the exhaust port 91, and the exhaust pipe 92.

When the COR processing is terminated, the partition walls 13 are lowered to the substrate transport position, and the wafers W on respective placement stages 11 are carried out to the outside of the wafer processing device 1 by the wafer transport mechanism (not illustrated). Thereafter, the wafers W are heated by a heating device (not illustrated) installed outside the wafer processing device 1, and a reaction product produced by the COR processing is vaporized and removed. In this way, a series of wafer processing steps are terminated.

According to the above embodiment, first, since the plurality of openings 81 communicating with the exhauster 15 are formed in the exhaust rings 52 at regular intervals around the entire circumferences of the exhaust rings 52, the processing gas flows out into the gaps 80 in the partition walls 13 uniformly over the entire circumferences of the wafers W and at a flow velocity rate that is lower than the flow velocity, for example, when the processing gas is exhausted downward from the entire circumferences of the peripheral portions of the wafers W as it is in conventional technologies. Moreover, since the openings 81 are formed at regular intervals around the entire circumferences of the exhaust rings 52, the flow of the processing gas in the peripheral portions of the wafers W is uniform.

In addition, the gaps 80 formed in the partition walls 13 extend in the vertical direction and are formed to be long, and the openings 81 communicating with the processing spaces S are formed at the entrances of the gaps 80 at a predetermined opening ratio. The opening areas R in which the openings 81 are formed are set to include the height position of the wafers W on the placement stages 11 while processing is performed in a state in which the partition walls 13 are raised to the substrate processing position. Therefore, the processing gas supplied to the wafers W flow in the horizontal direction directly toward the openings 81 in the partition walls 13. Here, since the opening ratio of the openings 81 is set within a predetermined range as described above, the flow velocity in the vicinity of the openings 81 is decelerated compared to that in a conventional one. When the exhaust of the processing gas flows from the openings 81 into the gaps 80, which become the exhaust flow paths in the partition walls 13, since the gaps 80 extends in the vertical direction, the flow velocity is still maintained in the decelerated state due to a corresponding pressure loss compared to that in the case in which the processing gas is directly discharged into an open space. As a result, since the staying time of the processing gas in the peripheral portions of the wafers W becomes longer, it is possible to make the etching rates more uniform in the wafer surfaces than that in a conventional one, and thus it is possible to improve the in-plane uniformity of the wafer processing.

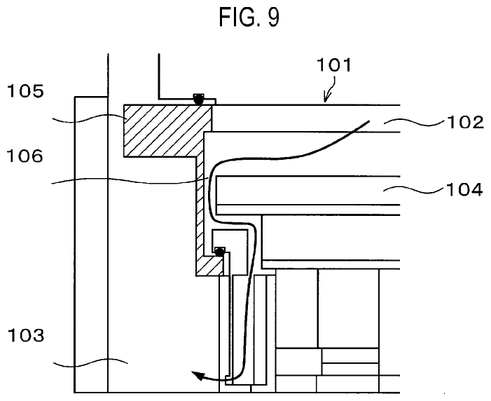

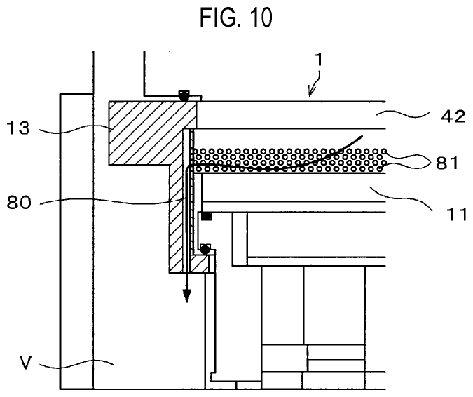

FIG. 9 illustrates an exhaust path of a processing gas in a conventional wafer processing device 101, that is, an device having a path for exhausting the processing gas on the wafer W downward from outside the peripheral portion of the wafer W. FIG. 9 is a vertical cross-sectional view illustrating only the left half of the wafer processing device 101, and the arrow in the figure represents a path in which the processing gas supplied from a shower head 102 reaches an exhaust space 103. FIG. 10 illustrates a similar vertical cross-sectional view in the embodiment of the present disclosure, and the arrow in the figure represents an exhaust path from the shower plate 42 to the exhaust space V, similar to FIG. 9.

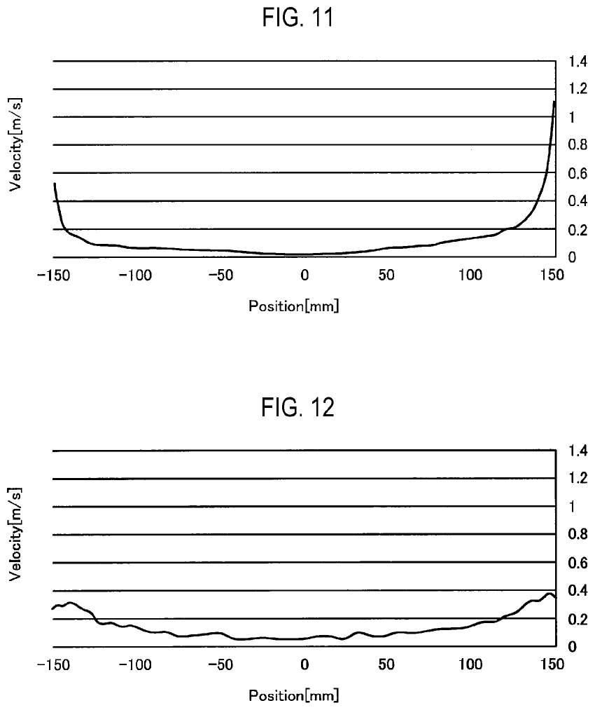

FIGS. 11 and 12 represent distributions of flow velocities at respective positions on wafer surfaces in FIG. 9 (the conventional wafer processing device 101) and FIG. 10 (the wafer processing device 1 according to the present embodiment). The horizontal axis in each figure represents a wafer surface position, in which the center position of 0 mm is, for example, the center of the wafer W placed on the placement stage 11 illustrated in FIG. 1, 150 mm in the positive direction represents the right end, and −150 mm in the negative direction represents the left end. In addition, the vertical axis in each figure represents a flow velocity at each position on the wafer, in which the larger value, the higher the flow velocity of the processing gas at that position.

As illustrated in FIG. 9, in the conventional wafer processing device 101, the processing gas supplied from the shower head 102 was guided to the exhaust space 103 via the gap 106 formed between the stage 104 having the placement stage and the partition wall 105 surrounding the stage 104. However, since the processing gas was directly guided to the gap 106 formed around the stage 104 in this manner, as illustrated in FIG. 11, the flow velocity of the processing gas in the vicinity of the gap 106, that is, in the vicinity of the peripheral edge of the wafer W was higher than the flow velocity at the center of the wafer W. As a result, the processing gas supplied above the peripheral portion of the wafer W from the shower plate 42 was exhausted before reaching the wafer W. It is considered that the flow velocity is increased because an opening communicating with the gap 106 has an annular shape surrounding the outer circumference of the stage 104, and the processing gas on the peripheral edge of the stage 104 immediately flows into the gap 106 and then immediately flows to the exhaust space 103, which is an enlarged space.

In exhausting the atmosphere in the exhaust space 103, since an exhaust port is usually set at the bottom of the processing container, a difference occurs in the flow velocity of the exhaust gas between a portion near the exhaust port and a portion far from the exhaust port, and the flow velocity is higher in the portion closer to the exhaust port. It is considered that the difference in the flow velocity affects the outflow from the outer circumference of the stage 104, which results in non-uniformity in the flow velocity of the exhaust gas in the peripheral portion of the wafer W, so that the staying time of the processing gas on the wafer W is shortened in the portion in which the flow velocity is high, which affects the in-plane uniformity of the wafer processing.

In contrast, in the present embodiment illustrated in FIG. 10, since the processing gas supplied from the shower plate 42 is guided to the exhaust space V through the openings 81 formed in the exhaust ring 52 and via the gap 80, which is the exhaust flow path formed inside the partition wall 13, the flow velocity of the processing gas is decelerated by the openings 81 before being guided to the exhaust flow path, and is then exhausted. Thus, the processing gas supplied above the peripheral portion of the wafer W from the shower plate 42 reaches the peripheral portion of the wafer W, thereby making the processing of the wafer W uniform. Since the openings 81 are formed at regular intervals over the entire circumference of the exhaust ring 52 of the partition wall 13, the processing gas is uniformly exhausted from the peripheral portion of the wafer W. In addition, since the gap 80, which is the exhaust flow path formed inside the partition wall 13, extends in the vertical direction, there is a corresponding flow path resistance. Accordingly, as represented in FIG. 12, the exhaust velocity in the peripheral portion of the wafer W is decelerated in the vicinity of the peripheral edge of the wafer W compared to that in the conventional one, and the uniformity of the exhaust velocity in the surface of the wafer W is also improved. That is, it is possible to improve the in-plane uniformity of wafer processing by improving the etching rate in the peripheral portion of the wafer W.

In the wafer processing device 1 according to the present embodiment, when the processing gas is exhausted by the exhaust mechanism 90, the processing gas is exhausted from the exhaust port 91 opened to the exhaust space V. In this case, it is considered that a difference occurs in the flow velocity at the time of exhaust between a place close to the exhaust port 91 and a place far from the exhaust port, thereby affecting the uniformity of the flow velocity of the evacuation around the wafer W.

However, in the present embodiment, as described above, since the processing gas flows through the gap 80 extending in the partition wall 13 in the vertical direction, the influence of the position of the exhaust port 91 is smaller than that in the conventional one. Moreover, in the present embodiment, since the plurality of slits 82 are formed at the lower side in the partition wall 13, the flow velocity of the exhaust gas in the gap 80, which becomes the exhaust flow path, is no longer affected by the position of the exhaust port 91 at a place close to the exhaust port 91 facing the exhaust space V and at a place far from the exhaust port 91. Accordingly, it is possible to suppress unevenness in the exhaust flow velocity in the peripheral portion of the wafer W, caused depending on the place in which the exhaust port 91 is installed.

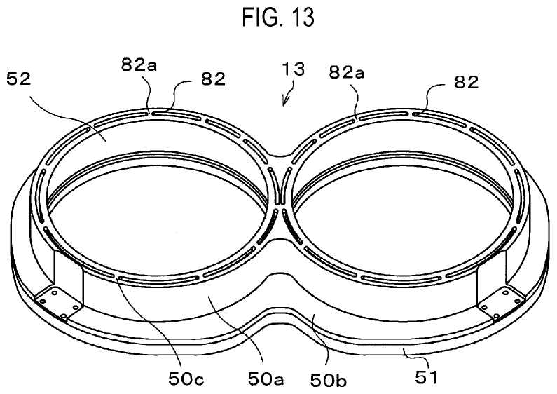

In order to further suppress the influence of the set position of the exhaust port 91 and further improve the uniformity of the exhaust flow velocity in the peripheral portion of the wafer W, for example, as illustrated in FIG. 13, the plurality of slits 82 formed at the lower side in the partition wall 13 may be formed to have a small size at a place near the exhaust port 91 and to have a relatively large size at a place far from the exhaust port 91 compared to those at the place near the exhaust port 91. Since this makes it possible to control the flow velocity of the processing gas flowing out from the gap 80 and the slits 82 to be constant, it is possible to prevent the exhaust flow velocity of the processing gas in the peripheral portion of the wafer W in the processing space S from being biased.

Further, in the above-described embodiment, for example, as illustrated in FIGS. 4 and 6, the opening area R in which the openings 81 are formed is set to include the same height position in the horizontal direction as the wafer W placed on the placement stage 11 in the state in which the partition wall 13 is raised to the substrate processing position and thus the processing space S is formed. Although the vertical setting range of the opening area R is the lower half of the portion forming the lateral circumferential surface of the processing space S when the partition wall 13 is located at the substrate processing position, the set height of the opening area R and the range in the vertical direction are not limited thereto as long as the height is set to include the same height position in the horizontal direction as the wafer W placed on the placement stage 11.

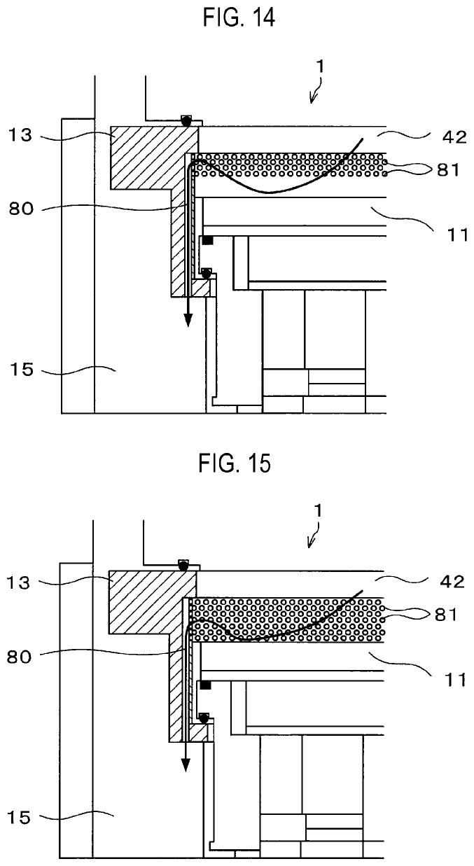

However, when the opening area R is set to be the upper half of the portion forming the lateral circumferential surface of the processing space S when the partition wall 13 is located at the substrate processing position, as illustrated in FIG. 14, even although the flow velocity of the processing gas flowing into the openings 81 may be kept constant, the processing gas flowing out from the end portion of the shower plate 42 flows toward the openings 81 formed in the upper portion. Therefore, the processing gas may not reach the end portion of the vicinity of the peripheral portion of the wafer W, and thus there is a possibility that etching is not sufficiently performed. That is, there is a possibility that in-plane uniformity of wafer processing is not be improved.

Meanwhile, when the opening area R is formed in the entire portion forming the lateral circumferential surface of the processing space S when the partition wall 13 is located at the substrate processing position, as illustrated in FIG. 15, the rise of the processing gas in the vicinity of the peripheral portion of the wafer W is alleviated compared with the case where the opening area is formed in the upper half as illustrated in FIG. 14. However, compared with the case where the opening area R is set in the lower half as in the embodiment, the processing gas discharged from the end portion of the shower plate 42 does not reach the end portion of the wafer W, and thus there is a possibility that the uniformity is not be improved.

According to the tests performed by the inventors, comparing the case where the opening area R was formed in the entire portion forming the lateral circumferential surface of the processing space S when the partition wall 13 was located at the substrate processing position with the case where the opening area R was formed in the lower half as in the embodiment, it was confirmed that in the actual COR processing, the in-plane uniformity of the etching amount in the wafer W was improved by 36, that is, improved by 4% in the embodiment. Therefore, it is desirable to set the opening area R in the lower half of the portion forming the lateral circumferential surface of the processing space S when the partition wall 13 is located at the substrate processing position.

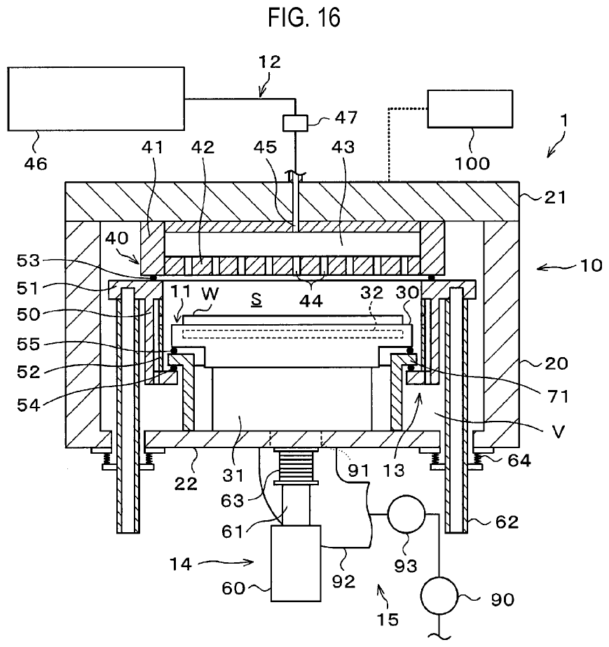

In the above embodiment, the description has been given based on the example in which the two placement stages 11 are installed as the plurality of placement stages. However, the number of placement stages 11 is not limited to two and may be one or may be three or more. FIG. 16 is a vertical cross-sectional view schematically illustrating the configuration of a wafer processing device 1 in the case where the number of placement stages 11 is one. In the case where the number of placement tables 11 is one, each of the number of cylinder portions 50a, the number of upper flange portions 50b, and the number of the lower flange portions 50c is also one in the base body 50 of the partition wall 13.

In the above embodiment, one partition wall 13 is installed for a plurality of placement tables. However, the configuration of the partition wall is not limited to the contents of the present embodiment. It is possible to arbitrarily set the shape of the processing space S as long as the independent processing space S is capable of being formed for each placement stage. For example, the base body 50 and the cover 51 may be configured to be individually formed for each processing space.

According to the present embodiment, since the exhaust gas of the processing gas inside the processing space S flows to the lower exhaust space V through the gap 80 formed in the partition wall 13, the exhaust gas is exhausted from the openings 81 in the exhaust ring 52 of the partition wall 13 facing the processing space S. However, the exhaust gas passing through the openings 81 does not flow out to the outside of the partition wall 13. Therefore, the space outside the partition wall 13 is not polluted by the exhaust gas of the processing gas. In addition, the exhaust gas from the processing space S does not flow out to the outside of the partition wall 13 and passes through the inside of the partition wall 13 as described above. Thus, when the processing container having two placement stages 11 as the plurality of placement stages according to in the embodiment is applied, side exhaust gases from the processing space S do not interfere with each other. In addition, the gap 80, which is the exhaust flow path, is formed independently for each processing space S, and from this viewpoint, exhaust gases from respective processing spaces S do not interfere with each other.

In addition, in the present embodiment, when forming the processing spaces S, the upper surface of the cover 51 and the frame 41 are configured to be in contact with each other. However, the present embodiment is not limited to such a configuration. For example, the ceiling plate 21 and the top surface of the cover 51 may be configured to be in contact each other.

The partition wall 13 in the present embodiment includes the base body 50, the cover 51, and the exhaust ring 52, which are separately configured, and is configured by fitting the exhaust ring 52 into the grooves 50d and 51d formed in the base body 50 and the cover 51, respectively. However, the present embodiment is not limited to this configuration. For example, respective components may be configured as a single-body component instead of individual components. Any two components, for example, the base body 50 and the cover 51, or the cylinder portion 50a and the exhaust ring 52 may be configured as a single body.

In the present embodiment, the plurality of slits 82 communicating with the exhaust space V via the gaps 80 are formed in the lower portions in the partition wall 13, but may be formed in the higher portions in the gaps 80. In addition, the gaps 80 are not limited to the slit shape, and may have any shape as long as the cross-sectional area of flow paths of the gaps 80 is reduced, which are the exhaust flow paths. Furthermore, although the gaps 80, which are the exhaust flow paths, are formed vertically downward, the gaps may be formed vertically upward instead. In such a case, the exhaust from the processing spaces S may be performed from above the partition wall 13, that is, near the cover 51.

The embodiments of the present disclosure have been described above, but the present disclosure is not limited to such examples. It is evident that a person ordinarily skilled in the art to which the present disclosure belongs is able to conceive various changes or modifications within the scope of the technical idea described in the claims, and it is understood that the changes or modifications naturally belong to the technical scope of the present disclosure. Although the above-described embodiments have been described by taking, as an example, the case where COR processing is performed on wafers, the present disclosure is also applicable to other wafer processing devices using a processing gas, such as a plasma processing device.

### EXPLANATION OF REFERENCE NUMERALS

1: wafer processing devices, 10: processing container, 11: placement stage, 12: gas supplier, 13: partition wall, 14: elevator, 15: exhauster, 50: base body, 51: cover, 52: exhaust ring, 80: gap, 81: opening, 82: slit, S: processing space, V: exhaust space, W: wafer

What is claimed is:

1. A substrate processing device for processing a substrate, the substrate processing device comprising:
a processing container configured to accommodate the substrate;
a placement stage on which the substrate is mounted in the processing container;
an exhauster configured to exhaust a processing gas in the processing container; and
a partition wall disposed in the processing container and surrounding the placement stage,
wherein, inside the partition wall, an exhaust flow path, which communicates with the exhauster, is formed to extend in a vertical direction over an entire circumference of the partition wall, and
a plurality of openings, which communicates with a substrate processing space formed inside the partition wall above the placement stage and communicates with the exhaust flow path, is formed at regular intervals in an inner circumferential direction of the partition wall.

2. The substrate processing device of claim 1, wherein a space is formed between the processing container and the partition wall, and an end portion of the exhaust flow path communicates with the space.

3. The substrate processing device of claim 1, further comprising:
an elevator configured to raise and lower the partition wall between a substrate transport position and a substrate processing position,
wherein the substrate processing space is formed when the partition wall is positioned at the substrate processing position.

4. The substrate processing device of claim 1, wherein an area in which the plurality of openings is formed in the partition wall is set in a range, which includes a height position of the substrate on the placement stage in a portion of the partition wall that forms a lateral circumferential surface of the substrate processing space.

5. The substrate processing device of claim 4, wherein the area in which the plurality of openings is formed in the partition wall is set in a lower half of the portion of the partition wall that forms the lateral circumferential surface of the substrate processing space.

6. The substrate processing device of claim 1, wherein the partition wall includes a base body, which surrounds the placement stage and has an inner circumference having a circular shape when viewed in a plan view, and a cylindrical exhaust ring installed inside the base body to be spaced apart from an inner surface of the base body, and
the plurality of openings is formed in the exhaust ring.

7. The substrate processing device of claim 1, wherein an opening ratio in the area in which the plurality of openings is formed is in a range of 45 to 55%.

8. The substrate processing device of claim 1, wherein an exhaust port of the exhauster is disposed outside the partition wall when viewed in a plan view.

9. The substrate processing device of claim 1, wherein, in the exhaust flow path inside the partition wall, a flow path cross-sectional area of a portion close to an exhaust port of the exhauster is smaller than a flow path cross-sectional area of a portion communicating with the plurality of openings.

10. The substrate processing device of claim 1, wherein a plurality of placement stages are installed inside the processing container, and
the partition wall, which individually surrounds the respective placement stages to form independent substrate processing spaces, is a single body.

11. The substrate processing device of claim 10, wherein the exhaust flow path is independently formed for each of the substrate processing spaces.
